(19) United States
(12) Patent Application Publication
(10) Pub. No.: US 2008/0237820 A1
(43) Pub. Date: Oct. 2, 2008

(54) Package structure and method of manufacturing the same

(75) Inventors: Hyeongno Kim, Paju-si (KR); Soo-Min Choi, Paju-Si (KR); Jae-Sun An, Paju-si (KR); Young-Gue Lee, Paju-Si (KR); Sang-Jin Cha, Paju-Si (KR)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/727,795

(22) Filed: Mar. 28, 2007

(51) Int. Cl. H01L 23/02

(52) U.S. Cl. 257/678

(57) ABSTRACT

A package structure including a substrate, a shielding element, a chip, a sealant layer and a semiconductor device is provided. The substrate has a first surface and a second surface opposite to the first surface. The shielding element is disposed on the first surface. The chip is disposed on the shielding element and is electrically connected to the substrate. The sealant layer is disposed on the first surface, and encapsulates the chip and the shielding element. The semiconductor device is disposed on the second surface.

### BACKGROUND OF THE INVENTION

1. Field of the Invention

The invention relates in general to a package structure and a method of manufacturing the same, and more particularly to a package structure having several semi-conductor chips and a method of manufacturing the same.

2. Description of the Related Art

In order to meet the market demand for highly integrated electronic products, the manufacturers are engaged in the development of new consumer electronic products having the features of lightweight, small size and multifunction. To achieve product miniaturization, multifunctional semiconductor devices having complex inner circuits are applied in the limited space of the electronic products. Regarding the packaging process of a semiconductor device, normally a semiconductor chip is bonded onto a substrate, and the pads of the chip are electrically connected to the pads of the substrate correspondingly via wire-bonding process or other electrically connecting processes, so that the semiconductor chip and internal circuits are electrically connected to the outside. However, as the pipelines of the semiconductor chip inside the semiconductor device tends to become more and more complicated, the number of the I/O pads on the chip and the density of the circuits on the substrate increase enormously.

Recently, a method of integrating several semiconductor chips into a single semicondcutor device is provided. The method achieves the integration of several semiconductor chips with different functions in the same package structure, therefore the semiconductor chips can work seamlessly together, and the performance of the semiconductor device increases substantially. Further more, it helps to reduce the number of semiconductor devices applied in electronic products, and the internal space of the electronic products can be utilized more effectively. However, electromagnetic interference is generated during operation of the semiconductor chips. Along with further miniaturization of the semiconductor devices, the interference raises due to the reduction of the distance between the semiconductor chips. In the integrated multifunctional electronic products nowadays, the interference within the semiconductor chips not only degrades the operation quality of the semiconductor devices, but also amplifies the noise of the semiconductor devices, and that the overall quality of the electronic products is lowered.

### SUMMARY OF THE INVENTION

The invention is directed to a package structure and a method of manufacturing the same. According to the design of the invention, a shielding element is disposed between the chip and the semiconductor device to shield the mutual electromagnetic interference that occurs during the operation of the chip and the semiconductor device. The invention is featured by the advantages of increasing operation stability, reducing the size, improving product quality and saving development cost.

According to the present invention, a package structure including a substrate, a shielding element, a chip, a sealant layer and a semiconductor device is provided. The substrate has a first surface and a second surface opposite to the first surface. The shielding element is disposed on the first surface. The chip is disposed on the shielding element and is electrically connected to the substrate. The sealant layer is disposed on the first surface, and encapsulates the chip and the shielding element. The semiconductor device is disposed on the second surface.

According to the present invention, a package structure including a substrate, a chip, a sealant layer and a semiconductor device is futher provided. The substrate having a first surface and a second surface opposite to the first surface includes a shielding element embedded in the substrate. The first surface has an opening exposing at least a part of the shielding element. The chip is disposed on the shielding element and electrically connected to the substrate. The sealant layer is disposed on the first surface and encapsulates the chip. The semiconductor device is disposed on the second surface.

The invention will become apparent from the following detailed description of the preferred but non-limiting embodiments. The following description is made with reference to the accompanying drawings.

### BRIEF DESCRIPTION OF THE DRAWINGS

FIG. 1A is a diagram of a substrate and a shielding element according to a first embodiment of the invention;

FIG. 1B is a diagram showing a shielding element disposed on the substrate in FIG. 1A;

FIG. 1C is diagram showing a chip disposed on the shielding element in FIG. 1B;

FIG. 1D is a diagram showing a sealant layer formed on the substrate in FIG. 1C;

FIG. 1E is a diagram of a package structure according to the first embodiment of the invention;

FIG. 2 is a diagram of the substrate in FIG. 1E;

FIG. 3 is a diagram of a shielding element having several material layers;

FIG. 4 is a diagram of a solder ball having several material layers; and

FIG. 5 is a diagram of a package structure according to a second embodiment of the invention.

### DETAILED DESCRIPTION OF THE INVENTION

Two embodiments are provided to elaborate the details of the invention. The difference between the two embodiments lies in the disposition of the shielding element in the package structure. However, the two embodiments are used as examples not for limiting the scope of protection of the invention, and are still within the scope of protection defined in the appended claims of the invention. Furthermore, unnecessary elements are omitted in the diagrams of the embodiments to highlight the technical features of the invention.

### First Embodiment

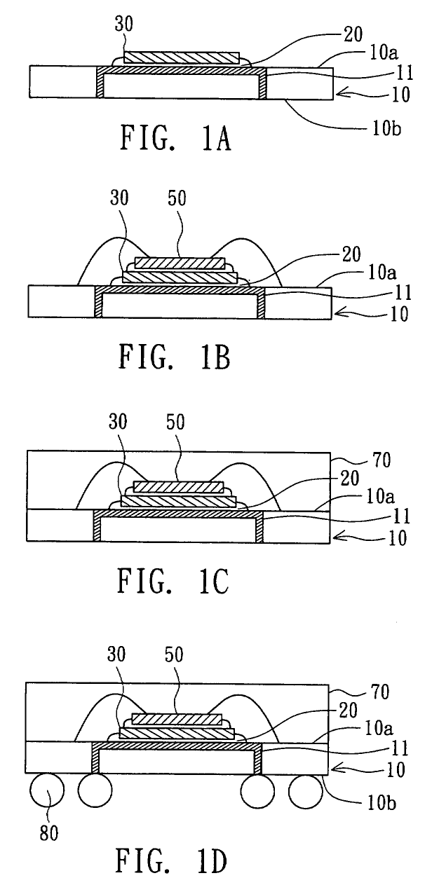

Referring to both FIGS. 1A-1E. FIG. 1A is a diagram of a substrate and a shielding element according to a first embodiment of the invention. FIG. 1B is a diagram showing a shielding element disposed on the substrate in FIG. 1A. FIG. 1C is a diagram showing a chip disposed on the shielding element in FIG. 1B. FIG. 1D is a diagram showing a sealant layer formed on the substrate in FIG. 1C. FIG, 1E is diagram of a package structure according to the first embodiment of the invention.

A method for manufacturing a package structure is disclosed in the present embodiment of the invention. First, a substrate 10 is provided, and a shielding element 30 is disposed on the substrate 10. As indicated in FIG. 1A, the substrate 10 has a first surface 10a and a second surface 10b opposite to the first surface 10a, and the shielding element 30 is disposed on the first surface 10a.

Next, a chip 50 disposed on the shielding element 30 is electrically connected (in this embodiment is wire-bonded) to the substrate 10, as indicated in FIG. 1B.

Afterwards, a sealant layer is formed and a solder ball is disposed on the substrate 10. As indicated in FIGS. 1C and 1D, the sealant layer 70 is formed on the first surface 10a and encapsulates the chip 50 and the shielding element 30. The solder ball 80 is disposed on the second surface 10b.

Then, a step of disposing a semiconductor device is performed. As indicated in FIG. 1E, a semiconductor device 90 is disposed on the second surface 10b of the substrate 10. After the semiconductor device 90 is disposed, the package structure 100 according to the first embodiment of the invention is completed.

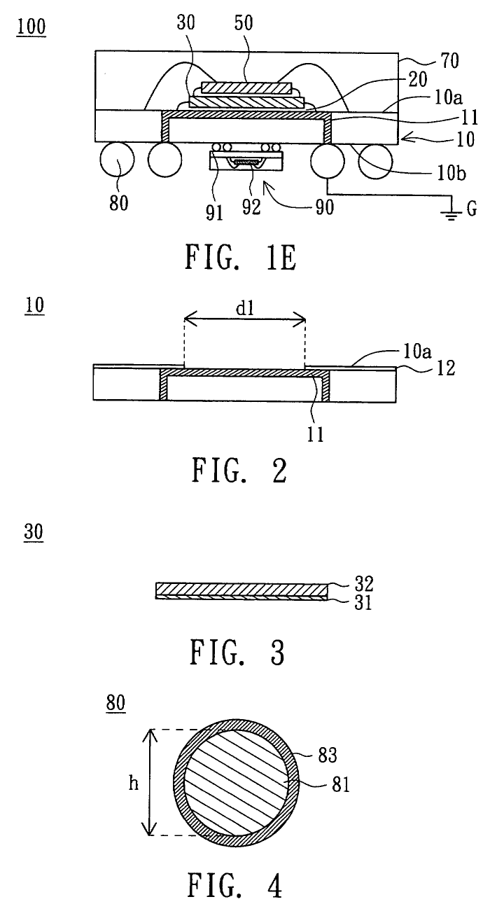

Referring to both FIG. 1E and FIG. 2. FIG. 2 is a diagram of the substrate in FIG. 1E. In the present embodiment of the invention, the substrate 10 includes a conductive layer 11 and a solder mask layer 12. The conductive layer 11 is positioned inside the substrate 10. The solder mask layer 12 has an opening d1 whose area is preferably equal to the area of the chip 50. The first surface 10a of the substrate 10 exposes at least a part of the conductive layer 11 via the opening d1. The conductive layer 11 is electrically connected to the solder ball 80. Besides, the shielding element 30 adhered onto the conductive layer 11 via a conductive adhesive 20 is electrically connected to an external ground G via the conductive adhesive 20, the conductive layer 11 and the solder ball 80. However, any one who is skilled in the field of the art will understand that the technology of the invention is not limited thereto. For example, the shielding element 30 can also be grounded via a grounding layer (not illustrated in the diagram) inside the substrate 10. The grounding layer is used for grounding the substrate 10. In an embodiment of the invention, the conductive layer 11 is the grounding layer of the substrate 10.

Besides as indicated in FIG. 1E, the semiconductor device 90 of the present embodiment of the invention includes a semiconductor device substrate 91 and a semiconductor device chip 92. The semiconductor device chip 92 is disposed on and wire-bonded to the semiconductor device substrate 91. The area of the semiconductor device substrate 91 is preferably smaller than the area of the substrate 10, so that the semiconductor device 90 and the solder ball 80 can be both disposed on the second surface 10b. Though the semiconductor device 90 is exemplified by a ball grid array package (BGA package) here, it can also be exemplified by a quad flat non-lead package (QFN package), a small outline j-lead package SOJ package) or a land grid array package (LGA package).

In the package structure 100 of the present embodiment of the invention, the shielding element 30 may include one metal layer or several material layers. Referring to FIG. 3, a diagram of a shielding element having several material layers is shown. The material layers at least include a conductive material layer 31 and a non-conductive material layer 33. The conductive material layer 31 is used for shielding the electromagnetic inteference from the chip 50 and the semiconductor device 90. The non-conductive material layer 33 prevents unexpected electrical connection between the chip 50 and the shielding element 30.

Next, in the present embodiment of the invention, the solder ball 80 includes several materials. Referring to FIG. 4, a diagram of a solder ball having several material layers is shown. The solder ball 80 includes a first solder 81 and a second solder 83 that envelops the first solder 81. The first solder 81 has a first melting point, and the second solder 83 has a second melting point. The first melting point is higher than the second melting point. Therefore, when reflows the solder ball 80 onto the substrate 10, the solder ball 80 remains at least the height h of the first solder 81. Such that, one sufficient space is provided beneath the substrate 10 for disposing the semiconductor device 90.

Besides, in the present embodiment of the invention, the area of the chip 50 is preferably larger than the area of the semiconductor device chip 92, and the area of the shielding element 30 is preferably larger than the area the chip 50 as indicated in FIG. 1E. That is, the shielding element 30 has sufficient area to shield both the chip 50 and the semiconductor device chip 92.

According to the package structure 100 and the method of manufacturing the same disclosed in the first embodiment of the invention, the shielding element 30 is disposed between the chip 50 and the semiconductor device 90, so that the interference between the chip 50 and the semiconductor device 90 is shielded, and that the stability in the operation of the chip 50 and the whole package structure 100 is improved. Besides, the shielding element 30 is composed of a conductive material layer 31 and a non-conductive material layer 33 for example, so that the shielding element 30 is connected to an external ground G. While the non-conductive material layer 33 prevents the chip 50 from electrically connecting to the shielding element 30, the shielding effect is further improved. Furthermore, the solder ball 80 is composed of different materials that have different melting points for maintining the height of the solder ball 80 as reflowing it onto the substrate 10, so that a sufficient space for disposing the semiconductor device 90 under the substrate 10 is assured. As a result, the fabrication quality of the package structure 100 is improved.

### Second Embodiment

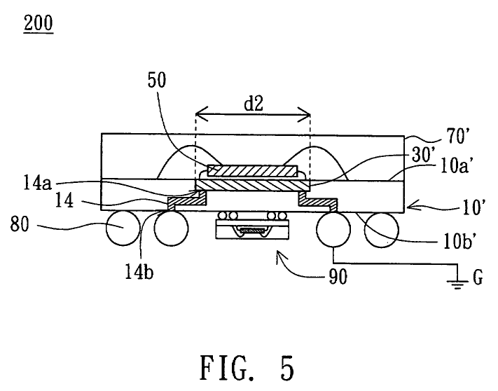

Referring to FIG. 5, a diagram of a package structure according to a second embodiment of the invention is shown. The package structure 200 includes a substrate 10′, a chip 50, a sealant layer 70′ and a semiconductor device 90. The package structure 200 of the present embodiment of the invention differs from the package structure 100 of the first embodiment of the invention in the disposition of the shielding element 30′ with respect to the substrate 10′ and the way of connecting the shielding element 30′ to the solder ball 80. Other similarities are not repeated herein.

In the present embodiment of the invention, the substrate 10′ has a first surface 10a′ and a second surface 10b′ opposite to the first surface 10a′. The substrate 10′ includes a shielding element 30′ embedded therein, and has an opening d2 exposing at least a part of the shielding element 30′. The chip 50 disposed on the shielding element 30′ is electrically connected to the substrate 10′. The sealant layer 70′ disposed on the first surface 10a′ encapsulates the chip 50. The semiconductor device 90 is disposed on the 115 second surface 10b′.

Furthermore, the substrate 10′ includes a conductive trace 14. The conductive trace 14 has a first end 14a and a second end 14b. The first end 14a is electrically connected to the shielding element 30′, and the second end 14b is electrically connected to the solder ball 80. That is, in the present embodiment of the invention, the shielding element 30′ is electrically connected to the external ground G via the conductive material 14 and the solder ball 80.

According to the package structure 200 disclosed in the second embodiment of the invention, the shielding element 30′ is embedded in the substrate 10′, so that the height of the package structure 200 is reduced. Because the sealant layer 70′ only needs to encapsulate the chip 50, the material cost for the sealant layer 70′ is then lowered.

According to the package structure and method of manufacturing the same disclosed in the above preferred embodiments of the invention, the shielding element is disposed between the chip and the semiconductor device to prevent the electromagnetic interference occurring when the chip and the semiconductor device operates, hence improve the stability in the operation of the package structure. Besides, the way of embedding the shielding element inside the substrate not only saves the material cost for the sealant layer, but also further reduces the size of the package structure. Furthermore, with the disposition of the solder ball composed of different materials with different melting points, the height of the solder ball is maintained when the solder ball reflows onto the second surface, so that the space for disposing the semiconductor device is reserved, and that the fabrication quality is improved. On the other hand, the package structure disclosed in the embodiments of the invention can be achieved simply by adding a shielding plate between the chip and the semiconductor device in the conventional package structure. The manufacturing process of the package structure disclosed in the embodiments of the invention is compactable with the existing manufacturing process of the package structure, hence the cost for developing a new manufacturing process is saved.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a substrate having a first surface and a second surface opposite to the first surface;
a shielding element disposed on the first surface;
a chip disposed on the shielding element and electrically connected to the substrate;
a sealant layer disposed on the first surface and encapsulating the chip and the shielding element; and
a semiconductor device disposed on the second surface.

2. The package structure according to claim 1, wherein the substrate comprises:
a conductive layer positioned in the substrate, wherein the first surface exposes at least a part of the conductive layer and the conductive layer is electrically connected to a solder ball.

3. The package structure according to claim 2, wherein the solder ball is disposed on the second surface.

4. The package structure according to claim 3, wherein the solder ball comprises:
a first solder having a first melting point; and
a second solder enveloping the first solder and having a second melting point;
wherein the first melting point is higher than the second melting point.

5. The package structure according to claim 3, wherein the shielding element is connected to the conductive layer and is electrically connected to an external ground via conductive layer and the solder ball.

6. The package structure according to claim 5, wherein the shielding element is adhered onto the conductive layer by a conductive adhesive.

7. The package structure according to claim 2, wherein the substrate further comprises:
a solder mask layer having an opening exposing at least a part of the conductive layer.

8. The package structure according to claim 7, wherein the area of the opening is substantially equal to the area of the chip.

9. The package structure according to claim 1, the substrate further comprising a grounding layer, wherein the shielding element is electrically connected to the grounding layer.

10. The package structure according to claim 1, wherein the area of the shielding element is larger than the area of the chip.

11. The package structure according to claim 1, wherein the shielding element comprises a plurality of material layers comprising at least a conductive material layer and a non-conductive material layer.

12. The package structure according to claim 1, wherein the area of the substrate is larger than the area of the semiconductor device.

13. The package structure according to claim 1, wherein the semiconductor device is selected from a group of a quad flat non-lead (QFN) package, a small outline J-lead (SOJ ) package, a ball grid array (BGA) package or a land grid array (LGA) package.

14. A package structure, comprises:
a substrate having a first surface and a second surface opposite to the first surface, wherein the substrate comprises:
a shielding element embedded in the substrate, wherein the first surface has an opening exposing at least a part of the shielding element;
a chip disposed on the shielding element and electrically connected to the substrate;
a sealant layer disposed on the first surface and encapsulating the chip; and
a semiconductor device disposed on the second surface.

15. The package structure according to claim 14, wherein the substrate further comprises:
a conductive trace having a first end and a second end, the first end electrically connecting to the shielding element, and the second end electrically connecting to a solder ball.

16. The package structure according to claim 15, wherein the solder ball is disposed on the second surface.

17. The package structure according to claim 16, wherein the solder ball comprises:
a first solder having a first melting point; and
a second solder enveloping the first solder and having a second melting point;
wherein the first melting point is higher than the second melting point.

18. The package structure according to claim 14, wherein the shielding element comprises a plurality of material layers comprising at least a conductive material layer and a non-conductive material layer.

19. The package structure according to claim 14, wherein the area of the opening is substantially equal to the area of the chip.

20. The package structure according to claim 14, wherein the area of the shielding element is larger than the area of the chip.

21. The package structure according to claim 14, wherein the semiconductor device is selected from a group of a quad flat no-lead (QFN) package, a small outline J-lead (SOJ ) package, a ball grid array (BGA) package or a land grid array (LGA) package.
